(19) United States
(12) Patent Application Publication
(10) Pub. No.: US 2022/0242101 A1
(43) Pub. Date: Aug. 4, 2022

(54) MULTILAYER POLYMERIC CUSHION FILMS FOR FOLDABLE DISPLAYS

(71) Applicant: Eastman Chemical Company, Kingsport, TN (US)

(72) Inventor: Wayne Ken Shih, Kingsport, TN (US)

(73) Assignee: Eastman Chemical Company, Kingsport, TN (US)

(21) Appl. No.: 17/596,542

(22) PCT Filed: Jun. 12, 2020
(86) PCT No.: PCT/US2020/037364

§ 371 Date: Dec. 13, 2021

Related U.S. Application Data
(60) Provisional application No. 62/866,754, filed on Jun. 26, 2019.

(51) Int. Cl. B32B 27/36; B32B 27/08; B32B 1/00; H01L 51/52

(52) U.S. Cl. CPC B32B 27/36; B32B 2457/206; B32B 1/00; H01L 51/5253; H01L 2251/5338; B32B 2250/02; B32B 2250/244; B32B 2250/40; B32B 2270/00; B32B 2307/412; B32B 2307/51; B32B 2307/54; B32B 2307/546; B32B 2307/558; B32B 2307/56; B32B 2307/702; B32B 2307/732; B32B 27/08

(57) ABSTRACT

This application discloses multilayer films suitable as cushion layers in foldable electronic displays. The multilayer films can absorb energy of impact from a falling or dropping object at low and high temperatures while satisfying the demand for bending cycles of foldable screens with acceptable recover rates after deformations from folding.

### BACKGROUND OF THE INVENTION

The global smartphone market growth is approaching saturation with the current rigid form factor where the LCD or OLED display is covered and protected with glass from falls or falling objects. OLED displays are poised to dominate smartphones and TVs over the next decade. In addition, customers prefer large screens on smartphones for video viewing and gaming. However, larger smartphones are difficult to handle, unless the screens become foldable, bendable and/or rollable when the large screen is not in use. A drawback to a foldable smartphones is that the screens can no longer be protected by glass. Therefore, polymeric (e.g., clear polyimide) protective screens will be necessary. With the use of polymeric protective screens, the OLED displays will be vulnerable to impact damage from a falling object or dropping without the protective glass screen. This application discloses a multilayer polyester-based cushion layer that can be used to absorb the energy of impact from a falling object or dropping. The cushion layer can be placed between the polymeric protective layer (e.g., polyimide) and the OLED display. The cushion layer disclosed in this application is able to sufficiently absorb impacts at low and high temperatures while satisfying the demand for bending cycles of such foldable screens with an acceptable recovery rate after deformations from folding.

### SUMMARY OF THE INVENTION

The present application discloses a multilayer film comprising:
(1) at least one of a first layer, comprising:
   60 to 100 weight % of a polyester elastomer, wherein the polyester elastomer comprises
      (a) a diacid component comprising 98 to 99.9 mole % of the residues derived from 1,4-cyclohexanedicarboxylic acid;
      (b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100 Da; and
      (c) 0.1 to 2 mole %, based on the mole % of the diacid component, of a branching agent derived from a compound having at least three functional groups selected from hydroxyl and carboxyl; and
   0 to 40 weight % of a cycloaliphatic polyester, wherein the cycloaliphatic polyester comprises
      (a) a diacid component comprising 100 mole % of the residues of 1,4-cyclohexanedicarboxylic acid,
      (b) a diol component comprising 100 mole % of the residues of 1,4-cyclohexanedimethanol; and
(2) at least one of a second layer, comprising
   5 to 35 weight % of a polyester elastomer, wherein the polyester elastomer comprises
      (a) a diacid component comprising 98 to 99.9 mole % of the residues derived from 1,4-cyclohexanedicarboxylic acid;
      (b) a diol component comprising 91 to 93 mole % of the residues derived from 1,4-cyclohexanedimethanol, and 7 to 9 mole % of the residues derived from poly(tetramethylene ether) glycol having a molecular weight of 500 to 1100; and
      (c) 0.1 to 2 mole %, based on the mole % of the diacid component, of a branching agent derived from a compound having at least three functional groups selected from hydroxyl and carboxyl; and
65 to 95 weight % of a cycloaliphatic polyester, wherein the cycloaliphatic polyester comprises
   (a) a diacid component comprising 100 mole % of the residues of 1,4-cyclohexanedicarboxylic acid,
   (b) a diol component comprising 100 mole % of the residues of 1,4-cyclohexanedimethanol.
      The application also discloses articles of manufacture comprising the multilayer films discloses herein.

### BRIEF DESCRIPTION OF THE DRAWINGS

FIG. 1 illustrates the bending of a cushion material.

FIG. 2 illustrates a typical stress-strain curve of a polymeric film.

FIG. 3 illustrates calculated bending deformation using a 50 μm of a polymeric cushion film by varying the bend radius from 1R to 4R.

FIG. 4 illustrates calculated bending deformation using a 100 μm polymeric cushion film by varying the bend radius from 1R to 4R.

FIG. 5 illustrates calculated bending deformation using a 150 μm polymeric cushion film by varying the bend radius from 1R to 4R.

FIG. 6 illustrates calculated bending deformation using a 200 μm polymeric cushion film by varying the bend radius from 1R to 4R.

FIG. 7 illustrates stress-strain curves of mono and multiple layer cushion films (Ex 4, 10, 15, and 16) at 20° C.

FIG. 8 illustrates stress-strain curves of mono and multiple layer cushion films (Ex 4, 10, 15, and 16) at 85° C.

### DETAILED DESCRIPTION OF THE INVENTION

### Definitions

The term “polyester”, as used herein, is intended to include “copolyesters” and is understood to mean a synthetic polymer prepared by the polycondensation of one or more difunctional carboxylic acids with one or more difunctional hydroxyl compounds. Typically, the polyesters are formed from at least one diacid and at least one diol. The polyester may comprise up to 2 mole percent, based on the total moles of diacid residues, of the residues of one or more branching agents having 3 or more carboxyl substituents, hydroxyl substituents, ionic forming groups, or a combination thereof, to improve melt strength and processability. Examples of branching agents include, but are not limited to, multifunctional acids or glycols such as trimellitic acid, trimellitic anhydride, pyromellitic dianhydride, trimethylolpropane, glycerol, pentaerythritol, citric acid, tartaric acid, 3-hydroxyglutaric acid and the like. The branching agent may be added to the polyester reaction mixture or blended with the polyester in the form of a concentrate as described, for example, in U.S. Pat. No. 5,654,347.

The term “residue”, as used herein, means any organic structure incorporated into a polymer through a polycondensation reaction involving the corresponding monomer. The term “repeating unit”, as used herein, means an organic structure having a dicarboxylic acid residue and a diol residue bonded through a carbonyloxy group. Thus, the dicarboxylic acid residues may be derived from a dicarboxylic acid or its associated acid halides, esters, salts, anhydrides, or mixtures thereof. As used herein, therefore, the term dicarboxylic acid is intended to include dicarboxylic acids and any derivative of a dicarboxylic acid, including its associated acid halides, esters, half-esters, salts, half-salts, anhydrides, mixed anhydrides, or mixtures thereof, useful in a polycondensation process with a diol to make a high molecular weight polyester.

The term “polyester elastomer”, as used herein, is understood to mean any polyester having a low modulus of about 1 to 500 MPa (at rt) which easily undergoes deformation and exhibits reversible elongations, under small applied stresses, i.e., elasticity. By the term “reversible”, as used herein, it is meant that the polyester returns to its original shape after any applied stress is removed. In general, these are prepared by conventional esterification/polycondensation processes from (i) one or more diols, (ii) one or more dicarboxylic acids, (iii) one or more long chain ether glycols, and optionally, (iv) one or more lactones or polylactones. For example, the polyester elastomer of the present invention may comprise (i) diacid residues comprising the residues of one or more diacids selected from substituted or unsubstituted, linear or branched aliphatic dicarboxylic acids containing 2 to 20 carbon atoms, substituted or unsubstituted, linear or branched cycloaliphatic dicarboxylic acids containing 5 to 20 carbon atoms, and substituted or unsubstituted aromatic dicarboxylic acids containing 6 to 20 carbon atoms; and (ii) diol residues comprising the residues of one or more substituted or unsubstituted, linear or branched, diols selected from aliphatic diols containing 2 to 20 carbon atoms, poly(oxyalkylene)-glycols and copoly-(oxyalkylene)glycols having an average molecular weight of about 400 to about 12000, cycloaliphatic diols containing 5 to 20 carbon atoms, and aromatic diols containing 6 to 20 carbon atoms. Representative dicarboxylic acids which may be used to prepare the polyester elastomer include, but are not limited to, 1,4-cyclohexanedicarboxylic acid; 1,3-cyclohexanedicarboxylic acid; terephthalic acid; isophthalic acid; sodiosulfoisophthalic acid; adipic acid; glutaric acid; succinic acid; azelaic acid; dimer acid; 2,6-naphthalene-dicarboxylic acid, and mixtures thereof. Preferred aliphatic acids include 1,4-cyclohexanedicarboxylic acid, sebacic acid, dimer acid, glutaric acid, azelaic acid, adipic acid, and mixtures thereof. Cycloaliphatic dicarboxylic acids such as, for example, 1,4-cyclohexanedicarboxylic acid may be present as the pure cis or trans isomer or as a mixture of cis and trans isomers. Preferred aromatic dicarboxylic acids include terephthalic, phthalic and isophthalic acids, sodiosulfoisophthalic, and 2,6-naphthalene-dicarboxylic acid, and mixtures thereof.

The polyester elastomer also may comprise the residues of at least one diol. Examples of diols include ethylene glycol; 1,3-propanediol; 1,4-butanediol; 1,5-pentanediol; 2-methylpropanediol; 2,2-dimethylpropanediol; 1,6-hexanediol; decanediol; 2,2,4,4-tetramethyl-1,3-cyclobutanediol; 1,3-cyclohexanedimethanol; 1,4-cyclohexanedimethanol; poly(ethylene ether)glycol; poly(propylene ether)glycol; and poly(tetramethylene ether)glycol. For example, the polyester elastomer may comprise the residues of a poly(oxyalkylene)glycol such as, for example, a poly(tetramethylene ether)glycol having an average molecular weight of about 400 to about 2000 Although not required, the polyester elastomer may comprise the residues of a branching agent having 3 or more carboxyl substituents, hydroxyl substituents, or a combination thereof. Examples of branching agents include, but are not limited to, multifunctional acids or glycols such as trimellitic acid, trimellitic anhydride, pyromellitic dianhydride, trimethylolpropane, glycerol, pentaerythritol, citric acid, tartaric acid, 3-hydroxyglutaric acid and the like. Examples of branching agent levels within the polyester elastomer are about 0.1 to about 2 mole %, about 0.1 to about 1 mole % and 0.25 to about 0.75 mole %, based on the total moles of diacid residues.

The term “cycloaliphatic polyester”, as used herein, means a polyester comprising a molar excess of the residues of cycloaliphatic dicarboxylic acids and/or cycloaliphatic diols. “Cycloaliphatic” as used herein with respect to the diols and dicarboxylic acids of the invention, refers to structures which contain as a backbone a cyclic arrangement of the constituent carbon atoms which may be saturated or paraffinic in nature, unsaturated, i.e., containing non-aromatic carbon-carbon double bonds, or acetylenic, i.e., containing carbon-carbon triple bonds. Typically, the difunctional carboxylic acid is a dicarboxylic acid and the difunctional hydroxyl compound is a dihydric alcohol such as, for example, glycols and diols.

The multilayer films of the invention may comprise articles of manufacture. Exemplary articles include a wearable device, a curved display, or a foldable electronic display. Small amounts of a hindered amine light stabilizer (HALS) may be added to the compositions for preparing the multilayer films or to the composition to scavenge radicals formed during the extrusion process or by photodegradation initiated from UV absorption by impurities that may be found in the cycloaliphatic polyester or polyester elastomer. Examples of HALS that may be used for this purpose include CHIMMASORB® 119, CHIMMASORB® 944, TINUVIN® 770, and others available from Ciba Specialty Chemicals and CYASORB® UV-3529 and CYASORB® UV-3346 available from Cytec Industries. HALS are usually used at levels of 0.1 to 1 weight percent. Additionally, some UV absorbing additive may also be added to the composition if the multilayer film is to be used as a protective layer over another surface. Examples of effective UV absorbers are: benzophenones such as TINUVIN® 81, CYASORB® UV-9, CYASORB® UV-24, and CYASORB® UV-531; benzotriazoles such as TINUVIN® 213, TINUVIN® 234, TINUVIN® 320, TINUVIN® 360, CYASORB® UV-2337, and CYASORB® UV-5411; triazines such as TINUVIN® 1577, and CYASORB® 1164; and benzoxazinone such as CYASORB® UV-3638 One or more oxidative stabilizers may be used in some instances to retard the breakdown of any polyester residues, if present. Examples of stabilizers that may be used for this purpose include hindered phenol stabilizers such as IRGANOX® 1010 and IRGANOX® 1076, which are typically used at levels of about 0.1 to about 1 weight percent.

The cycloaliphatic polyester and polyester elastomer may be dry blended or melt mixed in a single or twin-screw extruder or in a Banbury Mixer. For example, unoriented films may be prepared by the traditional methods such as chill roll casting, calendering, melt blowing, die extruding, injection molding, spinning, etc. For example, the high melt strength of the polyester elastomer will make the calendering of films at lower temperatures easier. Direct extrusion from the reactor as is common with many fiber operations is also possible. For example, in a typical procedure for preparing film, the melt is extruded through a slotted die using melt temperatures of about 200 to 280° C. and then cast onto a chill roll at about 20° C. to about 100° C. (70° F. to 210° F.). The optimal casting temperature will vary depending on the amount of elastomer in the composition. The formed film can have a nominal thickness of anywhere from about 20 to 600 μm depending on the final desired thickness of the film after stretching. Atypical optical film thickness range is 20 to 300 μm.

The films of the present invention may comprise one or more layers. When the film comprises multiple layers, it will have layers in communication with each other which can be achieved by methods such as coextrusion, lamination, microlayer coextrusion and the like as known in the art. The multilayer films can be put together by the use of optically clear adhesives. Further, the multiple layers can be arranged in any order desirable, including, for example, layering arrangements such as polyester elastomer/cycloaliphatic, polyester elastomer/cycloaliphatic/polyester elastomer, or cycloaliphatic/polyester elastomer/cycloaliphatic.

### Multilayer Films

The present application also a multilayer film comprising at least one of a first layer having a Young's modulus that is from 150 MPa to 500 MPa at 20° C., and at least one of a second layer having a Young's modulus that is from 100 MPa to 450 MPa at 85° C.

In one embodiment, the multilayer film further comprises a polyimide protective film.

In one embodiment, the multilayer film has a layering arrangement comprising an A/B, an A/B/A, or a B/A/B layering arrangement, wherein the A layer is the first layer, and the B layer is the second layer.

In one class of this embodiment, the first layer has a thickness of from 10 to 150 microns; and the second layer has a thickness of from about 10 to 150 microns. In one subclass of this class, the first layer has a thickness of from 25 to 100 microns; and the second layer has a thickness of from 25 to 100 microns.

In one class of this embodiment, the multilayer film has a layering arrangement which is an A/B layering arrangement.

In one subclass of this class, the multilayer film has at least one layer having a Young's modulus greater 150 MPa and less than 500 MPa at room temperature, and at least another layer having a Young's modulus greater than 100 MPa and less than 450 MPa at 85° C.

In one subclass of this class, the first layer has a thickness of from 10 to 150 microns; and the second layer has a thickness of from about 10 to 150 microns. In one sub-subclass of this subclass, the first layer has a thickness of from 25 to 100 microns; and the second layer has a thickness of from 25 to 100 microns.

In one class of this embodiment, the multilayer film has a layering arrangement which is an A/B/A layering arrangement.

In one subclass of this class, the multilayer film has at least one layer having a Young's modulus greater 150 MPa and less than 500 MPa at room temperature, and at least another layer having a Young's modulus greater than 100 MPa and less than 450 MPa at 85° C.

In one subclass of this class, the first layer has a thickness of from 10 to 150 microns; and the second layer has a thickness of from about 10 to 150 microns. In one sub-subclass of this subclass, the first layer has a thickness of from 25 to 100 microns; and the second layer has a thickness of from 25 to 100 microns.

In one class of this embodiment, the multilayer film has a layering arrangement which is a B/A/B layering arrangement.

In one subclass of this class, the multilayer film has at least one layer having a Young's modulus greater 150 MPa and less than 500 MPa at room temperature, and at least another layer having a Young's modulus greater than 100 MPa and less than 450 MPa at 85° C.

In one subclass of this class, the first layer has a thickness of from 10 to 150 microns; and the second layer has a thickness of from about 10 to 150 microns. In one sub-subclass of this subclass, the first layer has a thickness of from 25 to 100 microns; and the second layer has a thickness of from 25 to 100 microns.

In one embodiment, the multilayer film has a thickness of not greater than 300 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the multilayer film has a thickness of not greater than 275 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the multilayer film has a thickness of not greater than 250 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the multilayer film has a thickness of not greater than 225 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the multilayer film has a thickness of not greater than 200 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the multilayer film has a thickness of not greater than 175 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the multilayer film has a thickness of not greater than 150 microns. In one class of this embodiment, the first layer has a thickness of from 10 to 150 microns; and the second layer has a thickness of from about 10 to 150 microns. In one subclass of this subclass, the first layer has a thickness of from 25 to 100 microns; and the second layer has a thickness of from 25 to 100 microns.

In one embodiment, the first layer has a thickness of from 10 to 150 microns; and the second layer has a thickness of from about 10 to 150 microns. In one class of this embodiment, the multilayer film has a layering arrangement comprising an A/B, an A/B/A, or a B/A/B layering arrangement, wherein the A layer is the first layer, and the B layer is the second layer.

In one embodiment, the first layer has a thickness of from 25 to 100 microns; and the second layer has a thickness of from about 25 to 100 microns. In one class of this embodiment, the multilayer film has a layering arrangement comprising an A/B, an A/B/A, or a B/A/B layering arrangement, wherein the A layer is the first layer, and the B layer is the second layer.

In one embodiment, the first layer comprises a polyester, polyester elastomer, a silicone, thermoplastic polyurethane, thermoplastic olefin, or a styrene-butadiene. In one class of this embodiment, the second layer comprises a polyester, polyester elastomer, a silicone, thermoplastic polyurethane, thermoplastic olefin, or a styrene-butadiene.

The present application discloses a multilayer film comprising: (1) at least one of a first layer, comprising: 60 to 100 weight % of a polyester elastomer, wherein the polyester elastomer comprises: (a) a diacid component comprising 98 to 99.9 mole % of the residues derived from 1,4-cyclohexanedicarboxylic acid; (b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100 Da; and (c) 0.1 to 2 mole %, based on the mole % of the diacid component, of a branching agent derived from a compound having at least three functional groups selected from hydroxyl and carboxyl; and 0 to 40 weight % of a cycloaliphatic polyester, wherein the cycloaliphatic polyester comprises: (a) a diacid component comprising 100 mole % of the residues of 1,4-cyclohexanedicarboxylic acid, (b) a diol component comprising 100 mole % of the residues of 1,4-cyclohexanedimethanol; and (2) at least one of a second layer, comprising: 5 to 35 weight % of a polyester elastomer, wherein the polyester elastomer comprises: (a) a diacid component comprising 98 to 99.9 mole % of the residues derived from 1,4-cyclohexanedicarboxylic acid; (b) a diol component comprising 91 to 93 mole % of the residues derived from 1,4-cyclohexanedimethanol, and 7 to 9 mole % of the residues derived from poly(tetramethylene ether) glycol having a molecular weight of 500 to 1100; and (c) 0.1 to 2 mole %, based on the mole % of the diacid component, of a branching agent derived from a compound having at least three functional groups selected from hydroxyl and carboxyl; and 65 to 95 weight % of a cycloaliphatic polyester, wherein the cycloaliphatic polyester comprises: (a) a diacid component comprising 100 mole % of the residues of 1,4-cyclohexanedicarboxylic acid, (b) a diol component comprising 100 mole % of the residues of 1,4-cyclohexanedimethanol.

In one embodiment, the multilayer film further comprises a polyimide protective film.

In one embodiment, the multilayer film has a layering arrangement comprising an A/B, an A/B/A, or a B/A/B layering arrangement, wherein the A layer is the first layer, and the B layer is the second layer.

In one class of this embodiment, the multilayer film has at least one layer having a Young's modulus greater 150 MPa and less than 500 MPa at room temperature, and at least another layer having a Young's modulus greater than 100 MPa and less than 450 MPa at 85° C.

In one class of this embodiment, the multilayer film has a layering arrangement which is an A/B layering arrangement.

In one subclass of this class, the multilayer film has at least one layer having a Young's modulus greater 150 MPa and less than 500 MPa at room temperature, and at least another layer having a Young's modulus greater than 100 MPa and less than 450 MPa at 85° C.

In one class of this embodiment, the multilayer film has a layering arrangement which is an A/B/A layering arrangement.

In one subclass of this class, the multilayer film has at least one layer having a Young's modulus greater 150 MPa and less than 500 MPa at room temperature, and at least another layer having a Young's modulus greater than 100 MPa and less than 450 MPa at 85° C.

In one class of this embodiment, the multilayer film has a layering arrangement which is a B/A/B layering arrangement. In one subclass of this class, the multilayer film has at least one layer having a Young's modulus greater 150 MPa and less than 500 MPa at room temperature, and at least another layer having a Young's modulus greater than 100 MPa and less than 450 MPa at 85° C.

In one embodiment, the multilayer film has a thickness of not greater than 300 microns.

In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the multilayer film has a thickness of not greater than 275 microns.

In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the multilayer film has a thickness of not greater than 250 microns.

In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the multilayer film has a thickness of not greater than 225 microns. In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the multilayer film has a thickness of not greater than 200 microns. In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the multilayer film has a thickness of not greater than 175 microns. In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the multilayer film has a thickness of not greater than 150 microns. In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one embodiment, the first layer has a thickness of from 10 to 150 microns; and the second layer has a thickness of from about 10 to 150 microns. In one class of this embodiment, the multilayer film has a layering arrangement comprising an A/B, an A/B/A, or a B/A/B layering arrangement, wherein the A layer is the first layer, and the B layer is the second layer.

In one embodiment, the first layer has a thickness of from 25 to 100 microns; and the second layer has a thickness of from about 25 to 100 microns. In one class of this embodiment, the multilayer film has a layering arrangement comprising an A/B, an A/B/A, or a B/A/B layering arrangement, wherein the A layer is the first layer, and the B layer is the second layer.

### Article of Manufacture

The present application discloses an article of manufacture which comprises a multilayer film comprising: (1) at least one of a first layer, comprising: 60 to 100 weight % of a polyester elastomer, wherein the polyester elastomer comprises: (a) a diacid component comprising 98 to 99.9 mole % of the residues derived from 1,4-cyclohexanedicarboxylic acid; (b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100 Da; and (c) 0.1 to 2 mole %, based on the mole % of the diacid component, of a branching agent derived from a compound having at least three functional groups selected from hydroxyl and carboxyl; and 0 to 40 weight % of a cycloaliphatic polyester, wherein the cycloaliphatic polyester comprises: (a) a diacid component comprising 100 mole % of the residues of 1,4-cyclohexanedicarboxylic acid, (b) a diol component comprising 100 mole % of the residues of 1,4-cyclohexanedimethanol; and (2) at least one of a second layer, comprising: 5 to 35 weight % of a polyester elastomer, wherein the polyester elastomer comprises: (a) a diacid component comprising 98 to 99.9 mole % of the residues derived from 1,4-cyclohexanedicarboxylic acid; (b) a diol component comprising 91 to 93 mole % of the residues derived from 1,4-cyclohexanedimethanol, and 7 to 9 mole % of the residues derived from poly(tetramethylene ether) glycol having a molecular weight of 500 to 1100; and (c) 0.1 to 2 mole %, based on the mole % of the diacid component, of a branching agent derived from a compound having at least three functional groups selected from hydroxyl and carboxyl; and 65 to 95 weight % of a cycloaliphatic polyester, wherein the cycloaliphatic polyester comprises: (a) a diacid component comprising 100 mole % of the residues of 1,4-cyclohexanedicarboxylic acid, (b) a diol component comprising 100 mole % of the residues of 1,4-cyclohexanedimethanol.

In one embodiment, the multilayer film further comprises a polyimide protective film.

In one embodiment, the multilayer film has a layering arrangement comprising an A/B, an A/B/A, or a B/A/B layering arrangement, wherein the A layer is the first layer, and the B layer is the second layer. In one class of this embodiment, the first layer has a thickness of from 10 to 150 microns; and the second layer has a thickness of from about 10 to 150 microns. In one class of this embodiment, the first layer has a thickness of from 25 to 100 microns; and the second layer has a thickness of from 25 to 100 microns.

In one class of this embodiment, the multilayer film has a layering arrangement which is an A/B layering arrangement. In one class of this embodiment, the multilayer film has a layering arrangement which is an A/B/A layering arrangement. In one class of this embodiment, the multilayer film has a layering arrangement which is a B/A/B layering arrangement.

In one embodiment, the multilayer film has a thickness of not greater than 300 microns. In one embodiment, the multilayer film has a thickness of not greater than 275 microns. In one embodiment, the multilayer film has a thickness of not greater than 250 microns. In one embodiment, the multilayer film has a thickness of not greater than 225 microns. In one embodiment, the multilayer film has a thickness of not greater than 200 microns. In one embodiment, the multilayer film has a thickness of not greater than 175 microns. In one embodiment, the multilayer film has a thickness of not greater than 150 microns.

In one embodiment, the first layer has a thickness of from 10 to 150 microns; and the second layer has a thickness of from about 10 to 150 microns. In one class of this embodiment, the multilayer film has a layering arrangement comprising an A/B, an A/B/A, or a B/A/B layering arrangement, wherein the A layer is the first layer, and the B layer is the second layer.

In one embodiment, the first layer has a thickness of from 25 to 100 microns; and the second layer has a thickness of from about 25 to 100 microns. In one class of this embodiment, the multilayer film has a layering arrangement comprising an A/B, an A/B/A, or a B/A/B layering arrangement, wherein the A layer is the first layer, and the B layer is the second layer.

In one embodiment, the article of manufacture is a wearable device, a curved display, or a foldable electronic display. In one class of this embodiment, the article of manufacture is a wearable device. In one subclass of this class, the wearable device is a continuous glucose monitoring system, or a health or fitness sensor. In one sub-subclass of this subclass, the wearable device is a continuous glucose monitoring system. the wearable device is a health or fitness sensor.

In one class of this embodiment, the article of manufacture is a curved display. In one class of this embodiment, the article of manufacture is a foldable electronic display. In one subclass of this class, the foldable display is an in-folding display or an out-folding display. In one subclass of this class, the foldable display is an in-folding display.

### Experimental Section

### Abbreviations

wt % is weight percent; % T is percent transmittance; Mw is weight average molecular weight; mol is mole(s); mol % is mole percent; μm is micrometer(s) or microns; ° C. is degree(s) Celsius; MPa is megapascal(s); rt or RT is room temperature;

### Compositions

### Polymer I

Polymer I is a polyester elastomer having the composition of 99.5 mol % of residues derived from 1,4-cyclohexanedicarboxylic acid, 91.1 mol % of residues derived from 1,4-cyclohexanedimethanol, 8.9 mol % of residues derived from poly(tetramethylene ether) glycol having a M_{w} of 500 to 1100, and 0.5 mol % of residues derived from trimellitic anhydride.

### Polymer II

Polymer II is a cycloaliphatic polyester having the composition of 100 mol % of 1,4-cyclohexanedicarboxylic acid, and 100 mol % of 1,4-cyclohexanedimethanol.

### Films

### Ex 1-11

Table 1 provides the preparation of films (Ex 1-11) made from Polymer I and Polymer II. The films were produced from melt processing of blends of Polymer I and Polymer II, followed by melt extrusion of the blends at 235-250° C. The pellets of Polymer I and Polymer II were dried before the extrusion at 55-65° C. for 8-12 h, and the blends were prepared by pellet-pellet mixing of Polymer I and Polymer II. The blends were then fed into a cast film extrusion line to produce 150 μm thick films. Polymer I/Polymer II blends are miscible at any ratios as shown in Table 1 with very low haze. The light transmittance for all samples is around 90%. Low haze and high visual light transmittance are required for optical film applications.

Table 1 provides examples of films prepared along with their thickness, composition and haze for each film.

TABLE 1

| | Thickness, | Polymer I, | Polymer I, | |
|---|---|---|---|---|
| Ex # | μm | wt % | wt % | Haze, % |
| 1 | 150 | 100 | 0 | 2.2 |
| 2 | 150 | 90 | 10 | 2.19 |
| 3 | 150 | 80 | 20 | 1.95 |
| 4 | 150 | 70 | 30 | 1.58 |
| 5 | 150 | 60 | 40 | 1.2 |
| 6 | 150 | 50 | 50 | 0.69 |
| 7 | 150 | 40 | 60 | 0.8 |
| 8 | 150 | 30 | 70 | 0.71 |
| 9 | 150 | 20 | 80 | 1.13 |
| 10 | 150 | 10 | 90 | 1.07 |
| 11 | 150 | 0 | 100 | 1.31 |

The tensile properties, as determined according to ASTM D882, of Ex 1-11 are shown in Table 2. Samples with high Polymer I content have greater elongation at break. Most importantly, the modulus can be increased with increasing Polymer II content while maintaining good optical properties due to excellent miscibility. The modulus of the blend increases with the increasing Polymer II content.

Based on the data in Table 2, the peak Young's modulus at rt and 85° C. can be found around 70-90 wt % Polymer II (Ex 8-10). At 85° C. Ex 8-10 provide the best cushioning. However, Ex 1-5 would perform better at providing cushioning at 0-40 Polymer I at rt, because the Young's modulus would be between 169 to 433 MPa. None of the Ex 1-11 would perform well at rt and at 85° C.

TABLE 2

| | | | 20° C. | | 85° C. | |
|---|---|---|---|---|---|---|
| | | | Yield | Young's | Yield | Young's |
| | Polymer | Polymer | Strain, | Modulus, | Strain, | Modulus, |
| EX # | I, wt % | II, wt % | % | MPa | % | MPa |
| 1 | 100 | 0 | 22 | 168 | 15 | 34 |
| 2 | 90 | 10 | 24 | 197 | 15 | 38 |
| 3 | 80 | 20 | 23 | 263 | 15 | 54 |
| 4 | 70 | 30 | 20 | 375 | 16 | 62 |
| 5 | 60 | 40 | 17 | 433 | 14 | 66 |
| 6 | 50 | 50 | 7 | 590 | 17 | 81 |
| 7 | 40 | 60 | 6 | 794 | 16 | 82 |
| 8 | 30 | 70 | 5 | 910 | 16 | 108 |
| 9 | 2 | 80 | 5 | 920 | 16 | 115 |
| 10 | 10 | 90 | 5 | 906 | 16 | 131 |
| 11 | 0 | 100 | 5 | 895 | 17 | 128 |

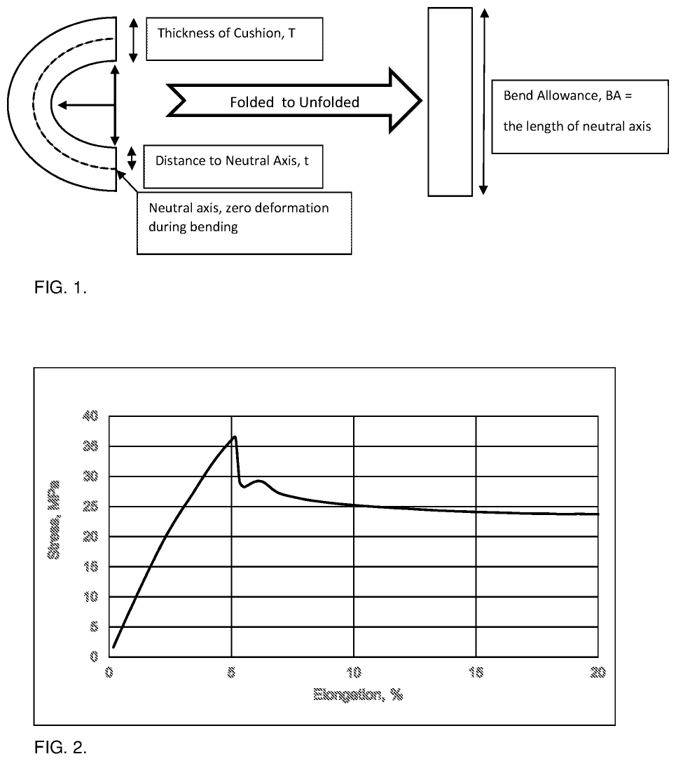

For foldable OLED displays, each layer must survive repeated bending without permanent deformation which may result in image distortions. FIG. 1 illustrates the folding and unfolding of a cushion layer. The neutral axis in bending is the line which experiences no stress thus no deformation. The length of the neutral axis is called bend allowance, which is calculated by Eq (8). The inside portion of the neutral axis will be under compressive stresses and thus decreases in dimension, while the outside portion of the neutral axis will be under tensile stresses and thus increases in dimension. It is critical that the cushion material can recover from tension and compression quickly after repeated bending cycles without permanent deformation.

$$B A = A ( \frac{}{180} ) ( R + K T ) \qquad Equation 8$$

where

BA: bend allowance, the length of neutral axis, mm.

A: bend angle, in degrees.

R: bend radius, mm.

T: cushion layer thickness, μm.

t: distance from inside surface to the neutral axis, μm.

K: K-factor=t/T=f(material, thickness, bend radius, . . . ), typically from 0.3-0.5.

FIG. 2 provides a typical stress-strain curve for a polymeric film. The elongation increases with tensile stress linearly before the yield point (about 5% in FIG. 2). The film returns to its original dimension when the load is removed. This elastic deformation is reversible and non-permanent. On the other hand, when the stress exceeds the elastic limit (˜5%), the film will be irreversibly deformed. Both modulus and yield strain are thus critical for the recovery of cushion layers to avoid permanent deformation in repeated folding.

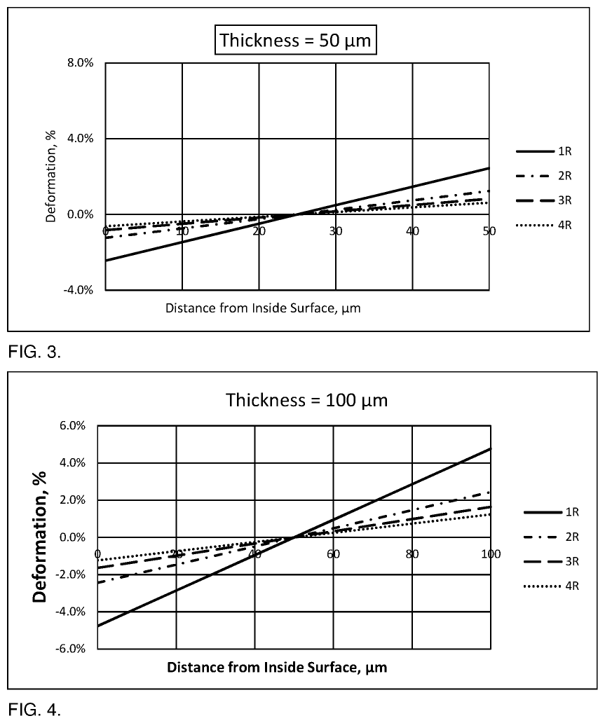

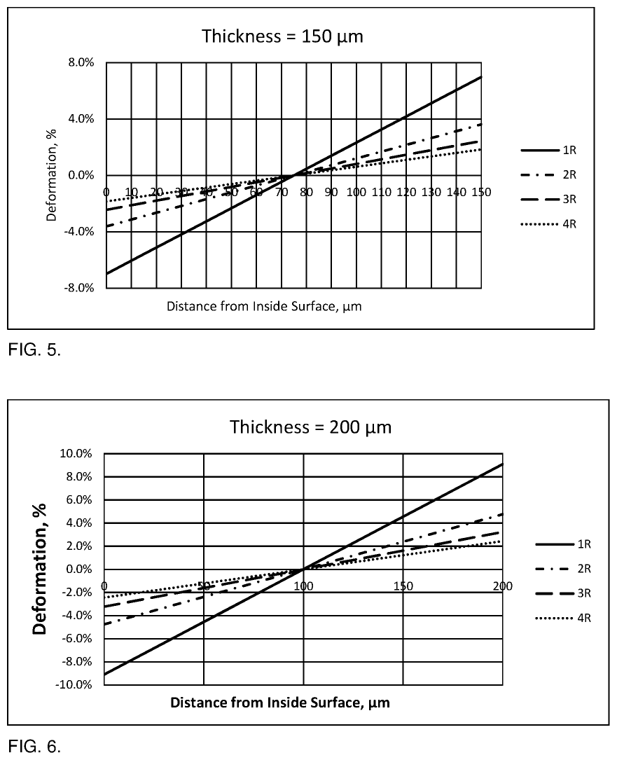

To avoid the permanent deformation of a film, the deformation limit of the film can be chosen to be +/−4% of the yield strain of 5%. FIGS. 3-7 show the deformation of the inner surface to the outer surface of the bend with K=0.5 and varying the total thickness and bend radius. For thinner cushion layers at 50 μm in thickness, the deformation is well within 4% even with small bend radius such as 1R (1 mm) in FIG. 3. By doubling the thickness to 100 μm, the deformation will exceed 4% for small bend radii at 1R as shown in FIG. 4. 2R may be needed to prevent permanent deformation of a cushion layer. For 150 μm cushion thickness, the deformation is approach 4% at 2R (2 mm) bend radius as shown in FIG. 5. The bend radius should be 3R (3 mm) or greater if 200 μm cushion is used as illustrated in FIG. 6. In conclusion, a thinner cushion is advantageous for small bend radius in inner folding OLED displays. A thicker film will be needed in out-folding OLED displays.

For elastic deformation, Hooke's law (Equation 9) can be applied.

F=−kx=−k(L−L_{O})=−kΔL Equation 9:

where F is the force, N.

x=ΔL is the elongation or compression, m.

k is called spring constant, N/m.

ΔL=L−L_{O}

L_{O} is the original length.

L is the length under applied force.

Young's modulus is defined in Equation 10

$$E = \frac{σ}{ɛ} = \frac{F / A}{Δ L / L} \qquad Equation 10$$

where E is Young's modulus, MPa.

σ=F/A is the stress, MPa.

ε=ΔL/L is the strain.

F is the force, N

A is the cross-sectional area, m²

By inserting Equation 9 into Equation 10 to give Equation 11, the spring constant can be equated to Young's modulus proportionally.

$$k = E \frac{A}{L} \qquad Equation 11$$

The recovery speed (time) of a compressed or extended spring can be calculated by conversation of energy. The potential energy results from spring extension (compression) can be fully transferred to the kinetic energy by assuming no other energy loss.

$$\frac{1}{2} m {v}^{2} = \frac{1}{2} k {x}^{2} \qquad Equation 12$$

where m is the mass, kg.

v is the velocity, m/s.

x is the displacement, m.

Equation 12 can be rearranged into Equation 13.

$$v = \sqrt{\frac{k}{m}} x \qquad Equation 13$$

By definition, velocity is the change in distance over the change in time, as shown in Equation 14.

$$v = \frac{d x}{d t} \qquad Equation 14$$

where t is the time, s.
By combining Equation 13 and Equation 14, Equation 15 is obtained.

$$d t = \frac{d x}{ν} = \sqrt{\frac{m}{k}} \frac{d x}{x} \qquad Equation 15$$

By integrating Equation 15, we get Equation 16.

$$t = \sqrt{\frac{m}{k}} ln ( x ) \qquad Equation 16$$

The recovery time (rate) of a cushion layer under elastic deformation can be expressed as the extent of deformation, spring constant and thus modulus of material as shown in Equation 16. A cushion material has higher modulus will recover quickly from deformation with a shorter time as illustrated in Equation 17. But rigid materials normally having lower yield strain and impact absorbance ability. This invention is intended to tackle these issues together.

$$t ∝ \frac{1}{\sqrt{k}} ∝ \frac{1}{\sqrt{E}} \qquad Equation 17$$

As shown in Table 2, none of Ex 1-11 individually provide adequate cushioning at rt and at 85° C. Table 3 provides multilayer films (Ex 15 and 16) prepared from Ex 4 and 10 in an A/B or A/B/A arrangement.

TABLE 3
Multilayer Films

| | Film | | | |
|---|---|---|---|---|
| EX # | Type | Layer 1 | Layer 2 | Layer 3 |
| 15 | A/B | Ex 10 | Ex 4 | |
| | | (150 μm) | (150 μm) | |
| 16 | A/B/A | Ex 10 | Ex 4 | Ex 10 |
| | | (150 μm) | (150 μm) | (150 μm) |

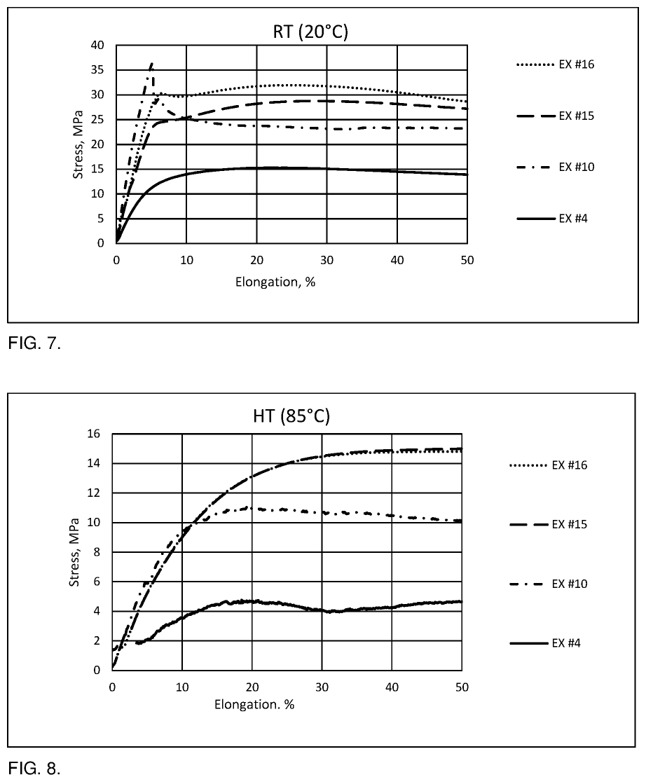

A cushion material such as an elastomer with a higher yield strain appears to be a better choice for both bending and impact. However, the modulus of an elastomeric material can be low which may slow down the rate of dimension recovery even if it can completely recover eventually. In addition, the modulus of an elastomeric material reduces drastically with increasing temperature. As a result, there will be a delay in the recovery at elevated temperatures. To overcome this dilemma, a multi-layer structure is invented to solve the problem. For example, Ex 4 is a polyester elastomer having a higher yield strain but lower modulus, and Ex 10 is a thermoplastic copolyester having lower yield strain but higher modulus. Two monolayers (Ex 4 and Ex 10), two-layer (Ex 15) and three-layer (Ex 16) multilayer films were tested using ASTM D882 for tensile properties at 20° C. and 85° C. Ex 4 and Ex 10 were heat laminated into a two-layer sample as Ex 12. Ex 10, Ex 4, and Ex 10 were laminated into a three-layer sample as Ex 16. FIG. 7-8 show the tensile stress-strain curves for these four samples at 20° C. and 85° C., respectively. The yield strain and modulus of each sample are shown in Table 5.

At 20° C., the lamination increases the yield strain of Ex 10 alone and improves the modulus of Ex 4. The sharp rising yield peak on Ex 10 is an indication of necking during stretching. Necking is a severe irreversible deformation. The necking in multilayered Ex 15 and Ex 16 is reduced drastically which is unexpected. The multilayers overall have higher yield strain, less necking, and moderate moduli. The bending and impact performance of a multilayered structure is therefore optimized.

At 85° C., Ex 4 has lower modulus again not desired for the deformation recovery rate. Ex 10 has an acceptable modulus, but it is prone to necking at rt. The multilayers maintain good moduli at high temperatures for better recovery rate and impact resistance.

Table 4 also provides the yield strain and Young's modulus for Ex 15 and 16.

TABLE 4
Properties of Multilayer Films

| | 20° C. | | 85° C. | |
|---|---|---|---|---|
| | | Young's | | Young's |
| | Yield | Modulus, | Yield | Modulus, |
| EX # | Strain, % | MPa | Strain, % | MPa |
| 15 | 7% | 659 | 20 | 133 |
| 16 | 8% | 742 | 20 | 147 |

In conclusion, Applicants have demonstrated a multilayer film suitable as cushion layer in curved, wearable or foldable displays. Moreover, this application provides (1) novel miscible blends with tunable modulus which perform differently at different temperatures, (2) multilayered cushion stack where at least one layer can take the impact at low temperature and at least another layer is capable of absorbing the energy of a falling object at high temperature while satisfies the overall bending performance. For monolayers, using two component miscible blends with tunable modulus and excellent optical properties such as transparency (>90%) and low haze (<1%) can be used for foldable OLED displays. Modulus and yield strain can be adjusted for bending and impact performance by using different blend ratios and thicknesses. If the monolayer approach is not sufficient in impact due to high temperature requirements, multilayer structures can be employed to optimize the modulus, yield strain, recovery speed, and low and high temperature impact in cushion layer. The yield point delays of the multilayer laminate as compared the individual layers are beneficial for improving the bending cycles with increased yield strain and reduced necking, which is unexpected.

Other embodiments will be apparent to those skilled in the art from consideration of the specification and practice of the embodiments disclosed herein. It will be understood that variations and modifications can be effected within the spirit and scope of the disclosed embodiments. It is further intended that the specification and examples be considered as exemplary only, with a true scope and spirit of the disclosed embodiments being indicated by the following claims.

1. A multilayer film comprising:
(1) at least one of a first layer, comprising:
60 to 100 weight % of a polyester elastomer, wherein the polyester elastomer comprises
(a) a diacid component comprising 98 to 99.9 mole % of the residues derived from 1,4-cyclohexanedicarboxylic acid;
(b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100; and
(c) 0.1 to 2 mole %, based on the mole % of the diacid component, of a branching agent derived from a compound having at least three functional groups selected from hydroxyl and carboxyl; and
0 to 40 weight % of a cycloaliphatic polyester, wherein the cycloaliphatic polyester comprises
(a) a diacid component comprising 100 mole % of the residues of 1,4-cyclohexanedicarboxylic acid,
(b) a diol component comprising 100 mole % of the residues of 1,4-cyclohexanedimethanol; and
(2) at least one of a second layer, comprising
5 to 35 weight % of a polyester elastomer, wherein the polyester elastomer comprises
(a) a diacid component comprising 98 to 99.9 mole % of the residues derived from 1,4-cyclohexanedicarboxylic acid;
(b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100; and
(c) 0.1 to 2 mole %, based on the mole % of the diacid component, of a branching agent derived from a compound having at least three functional groups selected from hydroxyl and carboxyl; and
65 to 95 weight % of a cycloaliphatic polyester, wherein the cycloaliphatic polyester comprises
(a) a diacid component comprising 100 mole % of the residues of 1,4-cyclohexanedicarboxylic acid,
(b) a diol component comprising 100 mole % of the residues of 1,4-cyclohexanedimethanol.

2. The multilayer film of claim 1, wherein the multilayer film has a layering arrangement comprising A/B, A/B/A, or B/A/B layering arrangement, wherein the A layer is the first layer, and the B layer is the second layer.

3. The multilayer film of claim 1, wherein the multilayer film has at least one layer having a Young's modulus greater 150 MPa and less than 500 MPa at room temperature, and at least another layer having a Young's modulus greater than 100 MPa and less than 450 MPa at 85° C.

4. The multilayer film of claim 1, wherein the multilayer film has a thickness of not greater than 200 microns.

5. The multilayer film of claim 1, wherein the first layer has a thickness of from 10 to 150 microns; and the second layer has a thickness of from about 10 to 150 microns.

6. An article of manufacture which comprises a multilayer film comprising:
(1) at least one of a first layer, comprising:
60 to 100 weight % of a polyester elastomer, wherein the polyester elastomer comprises
(a) a diacid component comprising 98 to 99.9 mole % of the residues derived from 1,4-cyclohexanedicarboxylic acid;
(b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100; and
(c) 0.1 to 2 mole %, based on the mole % of the diacid component, of a branching agent derived from a compound having at least three functional groups selected from hydroxyl and carboxyl; and
0 to 40 weight % of a cycloaliphatic polyester, wherein the cycloaliphatic polyester comprises
(a) a diacid component comprising 100 mole % of the residues of 1,4-cyclohexanedicarboxylic acid,
(b) a diol component comprising 100 mole % of the residues of 1,4-cyclohexanedimethanol; and
(2) at least one of a second layer, comprising
5 to 35 weight % of a polyester elastomer, wherein the polyester elastomer comprises
(a) a diacid component comprising 98 to 99.9 mole % of the residues derived from 1,4-cyclohexanedicarboxylic acid;
(b) a diol component comprising 91 to 93 mole % of the residues derived from 1,4-cyclohexanedimethanol, and 7 to 9 mole % of the residues derived from poly(tetramethylene ether) glycol having a weight average molecular weight of 500 to 1100; and
(c) 0.1 to 2 mole %, based on the mole % of the diacid component, of a branching agent derived from a compound having at least three functional groups selected from hydroxyl and carboxyl; and
65 to 95 weight % of a cycloaliphatic polyester, wherein the cycloaliphatic polyester comprises
(a) a diacid component comprising 100 mole % of the residues of 1,4-cyclohexanedicarboxylic acid,
(b) a diol component comprising 100 mole % of the residues of 1,4-cyclohexanedimethanol.

7. The article of manufacture of claim 6, wherein the multilayer film has a layering arrangement comprising A/B, A/B/A, or B/A/B layering arrangement, wherein the A layer is the first layer, and the B layer is the second layer.

8. The article of manufacture of claim 6, wherein the multilayer film has at least one layer having a Young's modulus greater 150 MPa and less than 500 MPa at room temperature, and at least another layer having a Young's modulus greater than 100 MPa and less than 450 MPa at 85° C.

9. The article of manufacture of claim 6, wherein the multilayer film has a thickness of not greater than 200 microns.

10. The article of manufacture of claim 6, wherein the first layer has a thickness of from 10 to 150 microns; and the second layer has a thickness of from about 10 to 150 microns.

11. The article of manufacture of claim 6, wherein the first layer has a thickness of from 25 to 100 microns; and the second layer has a thickness of from 25 to 100 microns.

12. The article of manufacture of claim 6, wherein the article of manufacture is a wearable device, a curved display, or a foldable electronic display.

13. The article of manufacture of claim 12, wherein the foldable electronic display is an in-folding display or an out-folding display.

14. The article of manufacture of claim 12, wherein the wearable device is a biosensor.

15. A multilayer film comprising at least one of a first layer having a Young's modulus that is from 150 MPa to 500 MPa at 20° C., and at least one of a second layer having a Young's modulus that is from 100 MPa to 450 MPa at 85° C.

16. The multilayer film of claim 15, wherein the multilayer film has a layering arrangement comprising A/B, A/B/A, or B/A/B layering arrangement, wherein the A layer is the first layer, and the B layer is the second layer.

17. The multilayer film of claim 15, wherein the multilayer film has a thickness of not greater than 200 microns.

18. The multilayer film of claim 15, wherein the first layer has a thickness of from 10 to 150 microns; and the second layer has a thickness of from about 10 to 150 microns.

19. The multilayer film of claim 15, wherein the first layer comprises a polyester, polyester elastomer, a silicone, thermoplastic polyurethane, thermoplastic olefin, or a styrene-butadiene; and the second layer comprises a polyester, polyester elastomer, a silicone, thermoplastic polyurethane, thermoplastic olefin, or a styrene-butadiene.

20. An article of manufacture comprising the multilayer film of claim 15, wherein the article of manufacture is a wearable device, a curved display, or a foldable electronic display.
